(19) United States
(12) Patent Application Publication
(10) Pub. No.: US 2004/0135501 A1
(43) Pub. Date: Jul. 15, 2004

(54) Organic electroluminescence panel

(76) Inventor: Ryuji Nishikawa, Gifu-shi (JP)

Correspondence Address: CANTOR COLBURN, LLP, 55 GRIFFIN ROAD SOUTH, BLOOMFIELD, CT, 06002

(21) Appl. No.: 10/713,620

(22) Filed: Nov. 13, 2003

(30) Foreign Application Priority Data
Nov. 14, 2002 (JP) 2002-331412

(51) Int. Cl. H05B 33/14; H05B 33/00

(52) U.S. Cl. 313/506; 313/509; 313/504

(57) ABSTRACT

In an active matrix organic EL panel comprising a plurality of organic EL elements formed above a substrate, in which each organic EL element includes at least an organic layer including an organic emissive material between a lower individual electrode which is individually patterned for each pixel and an upper electrode, an edge covering insulating layer is formed covering peripheral end portions of the lower individual electrode, and a mask supporting insulating layer having a thickness greater than the edge covering insulating layer for supporting a deposition mask used for formation of the organic layer is formed on the outer peripheral region with respect to the edge covering insulating layer. The organic layer extends to the outer region with respect to the boundary between the edge covering insulating layer and the lower individual electrode and terminates on the inner region with respect to a region where the mask supporting insulating layer is formed. The organic layer is individually patterned for each pixel. Damage of the organic layer or generation of dust, both cause by contacting the organic layer and the mask when the mask is aligned while supported by the mask supporting insulating layer can be prevented.

### BACKGROUND OF THE INVENTION

1. Field of the Invention

The present invention relates to an organic electroluminescence panel, and more particularly to an organic layer thereof.

2. Description of Related Art

Electroluminescence (referred to hereinafter as “EL”) panels comprising an EL element, which is a self-emissive element, as an emissive element for each pixel, are advantageous in that they are self emissive, are thin and consume less power. These electroluminescence panels have drawn attention as possible replacements for CRTs and LCDs, and have been the subject of much research and development.

In particular, active matrix EL panels, which comprise a thin film transistor (TFT) or the like for each pixel as a switching element for individually controlling the organic EL element and driving the EL element for each pixel, have been expected to be commercially developed as high resolution display panels.

An organic EL element includes an organic layer having organic emissive molecules between an anode and a cathode, and emits light using the following principle. Namely, holes injected from the anode and electrons injected from the cathode are recombined in the organic layer to excite the organic emissive molecules, and light is emitted when these excited molecules fall to their ground state.

In active matrix EL panels as described above, in order to control the EL element for each pixel, typically, on one of either the anode or the cathode serves as an individual electrode for each pixel and is connected to the TFT and the other electrode is formed as a common electrode for all the pixels. In one particular known structure, the anode, which is often a transparent electrode, is formed as a lower electrode and connected to the TFT, and the cathode, which is often a metal electrode, is formed as a common electrode; the anode (lower electrode), the organic layer, and the cathode (upper electrode) are sequentially layered in this order for radiating light outward through the substrate from the anode side.

In the above structure, the anode is individually patterned for each pixel and necessarily includes edge portions for each pixel. At these edges of the anode, concentration of electric field tends to occur. Also, because the organic layer is usually thin at these edges, it is likely that the anode and the cathode form a short circuit thereby causing deficient display. To deal with the problem, in U.S. Pat. No. 6,246,179, the present applicant suggests covering the edges of the anode with a planarization insulating film. Also, although not directed at ensuring covering the edges of the anode, Japanese Patent Laid-Open Publication No. Hei 11-24606 discloses a structure in which edges of the anode are covered with a bank layer made of an insulating material.

In the organic EL element, because the organic layer has rectification and also has relatively high electric resistance, for example, a region in which an anode and a cathode face each other with at least the organic emissive layer interposed between them corresponds to a light emission region. Thus, unlike the electrode, the organic layer need not be formed as an individual pattern in principle, and therefore can, in most cases, be formed over the entire substrate.

On the other hand, because it is necessary to use different organic emissive materials so as to obtain different emissive colors of R, G, and B, to create a multicolor display an individual organic emissive layer must be formed for each of R, G, and B.

When the organic layer is formed using vacuum evaporation, a film is patterned using a deposition mask simultaneously with formation of the film. Therefore, at the time of deposition, the deposition mask is aligned with an element forming substrate such that the opening of the deposition mask accurately corresponds to the position where the emissive layer is to be formed.

Alignment of the substrate and the deposition mask is performed by finely adjusting the deposition mask in a state where the mask is in contact with a surface of the substrate where the emissive layer is to be formed. Here, prior to the formation of the emissive layer, at least a hole transport layer has already been formed covering the anode and the planarization insulating film. Accordingly, when the deposition mask is aligned for forming the emissive layer, the hole transport layer is scraped by the deposition mask.

However, because the organic layer including the hole transport layer has a low mechanical strength, when the deposition mask is being aligned, the hole transport layer may be scraped off, or shavings from the hole transport layer may attach, as dust, to the emissive layer forming region. Also, dust which has attached to the deposition mask may be attached to the emissive layer forming region at the time of alignment. Removal of the hole transport layer and attachment of dust onto the emissive layer forming region as described above cause problems that the organic emissive layer formed on the hole transport layer deteriorates by mixture of dust and that the emissive layer cannot provide sufficient coverage for the uneven portions generated by the dust and is disconnected, resulting in deficient light emission.

### SUMMARY OF THE INVENTION

The present invention concerns an organic EL panel in which an organic layer is formed with more reliability.

In accordance with one aspect of the present invention, there is provided an organic electroluminescence panel in which a plurality of organic electroluminescence elements are formed above a substrate, each organic electroluminescence element including at least an organic layer including an organic emissive material between a lower individual electrode which is individually patterned for each pixel and an upper electrode, the organic electroluminescence panel comprising an edge covering insulating layer for covering peripheral end portions of the lower individual electrode, and a mask supporting insulating layer, which is formed on the outer peripheral region with respect to the edge covering insulating layer and has a greater thickness than the edge covering insulating layer, for supporting a mask, which is used when forming the organic layer, on a top surface thereof, wherein the organic layer terminates on the outer region with respect to the boundary between the edge covering insulating layer and the lower individual electrode, and on the inner region with respect to a region where the mask supporting insulating layer is formed, and the organic layer is individually patterned for each pixel.

In accordance with another aspect of the present invention, there is provided an organic electroluminescence panel in which a plurality of organic electroluminescence elements are formed above a substrate, each organic electroluminescence element including at least an organic layer including an organic emissive material between a lower individual electrode which is individually patterned for each pixel, and an upper electrode, the organic electroluminescence panel, comprising an edge covering insulating layer for covering peripheral end portions of the lower individual electrode, and an upper insulating layer which is formed on the outer peripheral region with respect to the edge covering insulating layer and has a greater thickness than the edge covering insulating layer, wherein the organic layer terminates on the outer region with respect to the boundary between the edge covering insulating layer and the lower individual electrode, and on the inner region with respect to a region where the upper insulating layer is formed, and the organic layer is individually patterned for each pixel.

In accordance with a further aspect of the invention, in the organic EL panel, the organic layer includes at least a hole injection layer and an organic emissive layer each formed by vacuum evaporation, and each of the hole injection layer and the organic emissive layer terminates on the inner region with respect to a region where the mask supporting insulating layer is formed.

In accordance with still another aspect of the present invention, in the organic EL panel, a charge transport layer is formed between the hole injection layer and the organic emissive layer and/or between the organic emissive layer and the upper electrode, and the charge transport layer terminates on the outer region with respect to the boundary between the edge covering insulating layer and the lower individual electrode, and on the inner region with respect to a region where the mask supporting insulating layer is formed, and the charge transport layer is individually patterned for each pixel.

Because the peripheral end portions of the lower individual electrode are covered with the edge covering insulating layer, reliable insulation can be provided between the lower individual electrode and the upper electrode formed on the lower electrode with the organic layer interposed between them. The mask supporting insulating layer, which has a greater thickness than the edge covering insulating layer for supporting the mask, is provided on the outer peripheral region with respect to the edge covering insulating layer. The organic layer terminates on the inner region with respect to the region where the mask supporting insulating layer is formed, and is not therefore formed on the supporting surface of the mask supporting insulating layer. Consequently, contact of the organic layer with the mask when aligning the mask, removal of the formed organic layer caused by scraping of the mask, and generation of dust can all be prevented.

Further, when an upper insulating layer, not necessarily the mask supporting insulating layer, which has a greater thickness than the edge covering insulating layer, is provided on the outer peripheral region with respect to the edge covering insulating layer, and the organic layer terminates on the inner region with respect to the region where the upper insulating layer is formed, the upper insulating layer can prevent the organic layer from coming into contact with the outer portions during transportation of the substrate or formation of the upper layers until the upper electrode is formed or the whole device is completed, after formation of the organic layer.

Also, because the organic layer is formed extending to the outer region with respect to the boundary between the edge covering insulating layer and the lower individual electrode, it is possible to prevent a variation of the contact area of the lower individual electrode and the organic layer, namely the light emission area, even when there is a slight deviation of the position at which the organic layer is formed.

In accordance with yet another aspect of the present invention, there is provided an organic electroluminescence panel in which a plurality of organic electroluminescence elements are formed above a substrate, each organic electroluminescence element including at least a hole injection layer and an organic emissive layer between a lower individual electrode which is individually patterned for each pixel and an upper electrode, the organic electroluminescence panel, comprising an edge covering insulating layer for covering peripheral end portions of the lower individual electrode, and a mask supporting insulating layer, which has a greater thickness than the edge covering insulating layer, for supporting a mask, which is used when forming an organic layer, on a top surface thereof, wherein the hole injection layer is formed covering the lower individual electrode, the edge covering insulating layer, and the mask supporting insulating layer, and the organic emissive layer is formed between the upper electrode and the hole injection layer and terminates on the outer region with respect to the boundary between the edge covering insulating layer and the lower individual electrode, and on the inner region with regard to a region where the mask supporting insulating layer is formed, and the organic emissive layer is individually patterned for each pixel.

In accordance with a further aspect of the present invention, the hole injection layer has a thickness which is smaller than 10 nm, and the organic emissive layer has a total thickness of 10 nm or greater.

Unlike other layers constituting the organic layer, the hole injection layer is usually very thin, has excellent adhesion to the insulting layer and the lower individual electrode formed underneath, and can be formed using a material having relatively high mechanical strength. Accordingly, it is not likely that the hole injection layer is removed, or is scraped and generates dust which adversely affects the upper organic layer, even when the mask comes contact with the hole injection layer at the time of forming the hole transport layer and the emissive layer in an individual pattern using the deposition mask provided on the hole injection layer. It is therefore possible to form the organic layer effectively and with high reliability by terminating only the layers constituting the organic layer other than the hole injection layer formed above the hole injection layer, such as the emissive layer and the charge transport layer, on the inner region with respect to the mask supporting insulating portion.

In accordance with another aspect of the present invention, the edge covering insulating layer and the mask supporting insulating layer are formed by patterning a single insulating layer in respective predetermined patterns having different thicknesses by means of multi-phase exposure or gray-tone exposure.

With the use of the multi-stage exposure, it is possible to form the mask supporting insulating layer and the edge covering insulating layer in the respective necessary regions without increasing the number of manufacturing processes.

As described above, according to the present invention, it is possible to prevent, in the processes after formation of the organic layer, the organic layer and members or the like which are used during these processes from coming into contact with each other and damaging the organic layer. Further, when the mask used for forming the organic layer is aligned, the mask can be supported by the mask supporting insulating layer which is formed on the outer region with respect to the edge covering insulating layer which covers the end portions of the lower individual electrode, and the organic layer is prevented from coming into contact with the deposition mask. It is therefore possible to reliably prevent removal of the organic layer having low mechanical strength and generation of dust caused by contact of the organic layer with the mask.

### BRIEF DESCRIPTION OF THE DRAWINGS

FIG. 1 schematically shows a circuit structure corresponding to one pixel of an active matrix organic EL panel in accordance with a first embodiment of the present invention;

FIG. 2 is a cross sectional view schematically showing a principal pixel portion of the active matrix organic EL panel according to the first embodiment of the present invention;

FIG. 3 is an explanatory view schematically showing a layout of the emissive region of the active matrix organic EL panel according to the first embodiment of the present invention;

FIG. 4 is a view for explaining a process of forming the organic layer using a deposition mask according to the first embodiment of the present invention; and

FIG. 5 is a cross sectional view schematically showing a principal pixel portion of the active matrix organic EL panel according to a second embodiment of the present invention.

### DESCRIPTION OF PREFERRED EMBODIMENTS

Preferred embodiments of the present invention will be described in further detail with reference to the accompanying drawings.

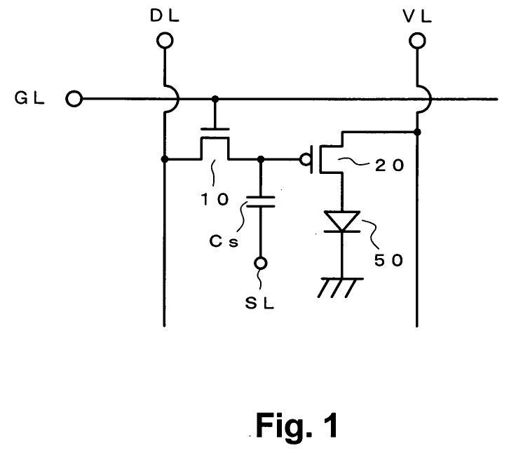

FIG. 1 shows a typical circuit structure corresponding to one pixel of an active matrix organic EL panel according to a first embodiment of the present invention. In an active matrix organic EL panel, on a substrate, a plurality of gate lines GL extend in the row direction, and a plurality of data lines DL and a plurality of power source lines VL extend in the column direction. Each pixel is formed in the vicinity of an intersection between the gate line GL and the data line DL, and each includes an organic EL element 50, a switching TFT (first TFT) 10, and an EL element driving TFT (second TFT) 20, and a storage capacitor Cs.

The first TFT 10 is connected with the gate line GL and the data line DL, and turns ON when a gate signal (selection signal) is applied to a gate electrode thereof. A data signal being supplied to the data line DL at this time is stored in the storage capacitor Cs which is connected between the first TFT 10 and the second TFT 20. A voltage in accordance with the data signal which is supplied via the first TFT 10 is supplied to a gate electrode of the second TFT 20. The second TFT 20 then applies electrical current in accordance with the voltage value from the power source line VL to the organic EL element 50. With this operation, the organic EL element 50 emits light of a brightness corresponding to the data signal for each pixel, to thereby display a desired image.

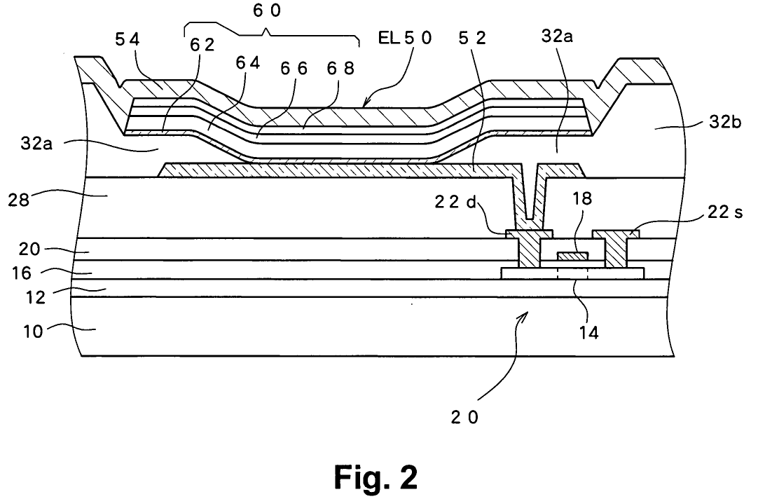

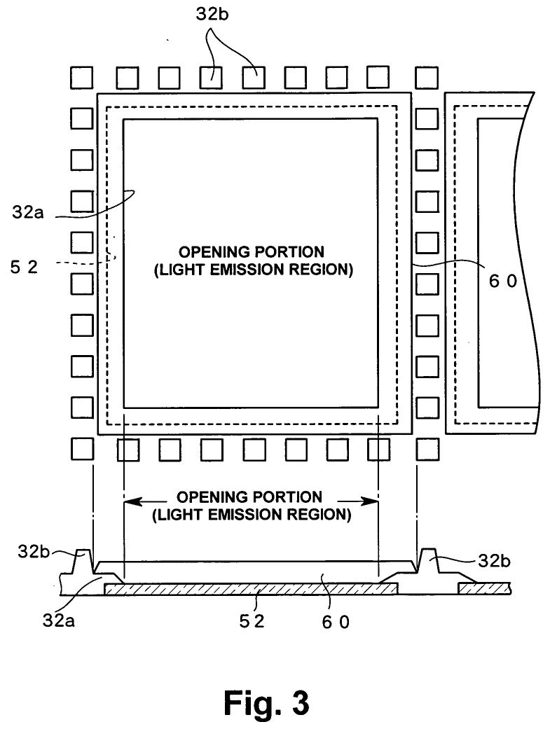

FIG. 2 is a cross sectional view showing a principal portion of the active matrix organic EL panel as described above. More specifically, FIG. 2 shows the second TFT 20 formed on the glass substrate 10, and the organic EL element 50 having the anode 52 connected with the second TFT 20. Further, FIG. 3 schematically shows a layout of the light emission region in one pixel of the active matrix organic EL panel.

The organic EL element 50 comprises an organic layer 60 including an organic emissive material between the anode 52 and a cathode 54. In the example shown in FIG. 2, the anode 52 (lower individual electrode) formed in an individual pattern for each pixel, the organic layer 60, and the cathode (upper electrode) 54 formed commonly for all the pixels, are sequentially laminated from the lower layer side.

On the glass substrate 10, a two-layered buffer layer 12 formed by sequentially laminating SiNx and SiO₂ in this order is formed so as to cover the entire surface, with a view to preventing invasion of impurities from the glass substrate 10. On the buffer layer 12, a great number of thin film transistors are formed for controlling the organic EL element for the respective pixels. In the example of FIG. 2, the second TFT 20 is shown, as described above, and the first TFT and the storage capacitor Cs are not shown. Further, in the peripheral region of the display section, a similar TFT is formed for a driver circuit for supplying a data signal and a gate signal to each pixel.

On the buffer layer 12, a semiconductor layer 14 made of polycrystalline silicon or the like is provided. A gate insulating film 16 which is a two-layered film formed by sequentially laminating SiO₂ and SiNx in this order is then formed covering the semiconductor layer 14. On the gate insulating film 16, a gate electrode 18 made of Cr, Mo or the like is formed. The region of the semiconductor layer 14 immediately under the gate electrode 18 corresponds to a channel region. Along both sides of the channel region, boron (B) or the like is doped, in the case of p-ch structure, or phosphorus (P) or the like is doped, in the case of n-ch structure, to thereby form a source-drain region. Then, on the gate electrode 18, an interlayer insulating film 20 formed by sequentially laminating SiNx and SiO₂ in this order is formed so as to cover the entire surface of the substrate, including the gate electrode 18. Contact holes are formed through the interlayer insulating film 20 and the gate insulating film 16. A source electrode 22s and a drain electrode 22d made of Al or the like are then formed within these contact holes, and are respectively connected with the source region and the drain region of the semiconductor layer 14 which are exposed at the bottom of the contact holes. The source electrode 22s (or the drain electrode 22d, depending on the conductivity of the second TFT 20) also functions as the power source line VL.

A first planarization insulating layer 28 made of an organic material such as an acrylic resin is then formed covering the interlayer insulating film 20, the source electrode 22s, and the drain electrode 22d over the entire surface of the substrate. A moisture blocking layer formed by an SiNx or TEOS film may be additionally provided between the first planarization insulating layer 28, and the interlayer insulating film 20 and the source and drain electrodes 22s, 22d.

On the first planarization insulating layer 28 is formed the lower electrode 52 of the organic EL element, which is individually patterned for each pixel. The lower electrode (referred to hereinafter as a pixel electrode) 52 functions as an anode as described above, and is formed by a transparent conductive material such as ITO. Also, the pixel electrode 52 is connected with the drain electrode 22d (or possibly the source electrode 22d depending on the conductivity type of the second TFT 20) which is exposed at the bottom of the contact hole having an opening through the first planarization insulating layer 28.

The pixel electrode 52 is individually formed for each pixel into a pattern, such as, for example, the pattern shown in FIG. 3. Subsequently, a second planarization insulating layer 32 is formed over the entire surface of the substrate in a manner that the pixel electrode 52 is covered with the second planarization insulating layer 32 only at the edges. Namely, the second planarization insulating film 32 has an opening in the light emission region of the pixel electrode 52. Further, the second planarization insulating layer 32 includes an edge covering portion 32a for covering the end portions of the pixel electrode 52 along the entire peripheral portion outlining the pixel electrode 52 and a thick upper insulating layer 32b formed on the outer region with respect to the edge covering portion 32a. The upper insulating layer 32b functions as a thick mask supporting portion which supports, on its top surface, a deposition mask used for forming the above-described organic layer 60 by vacuum evaporation. (Hereinafter, the upper insulating layer 32b will be described as a mask supporting portion 32b.) When the pixel electrode 52 is 60 μm square, for example, the width of the edge covering portion 32a of the second planarization insulating layer 32 is approximately 10˜20 μm. Although shown in an exaggerated manner in FIG. 2, sufficient edge protection can be ensured when the edge covering portion 32a overlaps the pixel electrode 52 by approximately several μm. Further, the shape of the mask supporting portion 32b may be, for example, a column (including a cone), a wall, or a frame which encloses the entire outer peripheral portion of the edge covering portion 32a. The width of the mask supporting portion 32b is not particularly limited as long as it can support the mask with minimum deformation.

While the second planarization insulating film 32 is formed using a resin such as an acrylic resin in the above example, the material for the second planarization insulating film 32 is not limited to a planarization material, and an insulating material such as TEOS (tetraethoxysilane) which can cover the end portions of the pixel electrode 52 and which can be formed into a relatively thick film may also be used.

In order to form the edge covering portion 32a and the mask supporting portion 32b at substantially the same time using the same insulating material, it is preferable to employ a process such as multi-stage exposure, gray-tone exposure, or the like.

In the case of multi-stage exposure, first, a second planarization insulating material consisting of an acrylic resin agent including a photosensitive agent is spin-coated over the entire surface of the substrate so as to cover the pixel electrode 52 formed on the first planarization insulating layer 28. Then, the first exposure is performed using a first photo mask having an opening corresponding to the region other than the mask supporting portion forming region. Further, the second exposure is performed using a second photo mask having an opening corresponding to the area other than the mask supporting portion forming region and the edge covering portion forming region. After the exposure, the second planarization insulating material is removed from the exposed region using an etching solution. Consequently, the second planarization insulating material is completely removed from the region which has been subjected to both the first and second exposure, namely the region corresponding to the light emission region. Second planarization insulating material in the edge covering portion forming region which has been once exposed has a reduced height. In the mask supporting portion forming region which has experienced no exposure, the second planarization insulating material having a desired thickness remains. In this manner, the opening portion, the edge covering portion 32a, and the mask supporting portion 32b are formed in the second planarization insulating layer 32.

In the case of gray-tone exposure, similar to the case of multi-stage exposure, a second planarization insulating material consisting of an acrylic resin agent including a photosensitive agent is spin-coated over the entire surface of the substrate. However, gray-tone exposure employs a single gray-tone mask having a fully opened portion and a gray-tone opening portion in which the numerical aperture is adjusted using dots and slits in accordance with a desired thickness. By performing a single exposure using a gray-tone mask, the region corresponding to the fully opened portion is subjected to a maximum exposure amount while the region corresponding to the gray-tone opening is subjected to an exposure amount in accordance with the numerical aperture. For example, the second planarization material in the maximum exposure region is completely removed, the second planarization material in the gray-tone exposure region has reduced thickness in accordance with the exposure amount, and the second planarization material in the region which has not been exposed remains unaffected. In this manner, the opening portion, the edge covering portion 32a, and the mask supporting portion 32b can also be formed in the second planarization insulating layer 32.

It should be noted that, when the edge covering portion 32a and the mask supporting portion 32b are formed in different steps or from different materials, neither of the above-described forming methods are necessary.

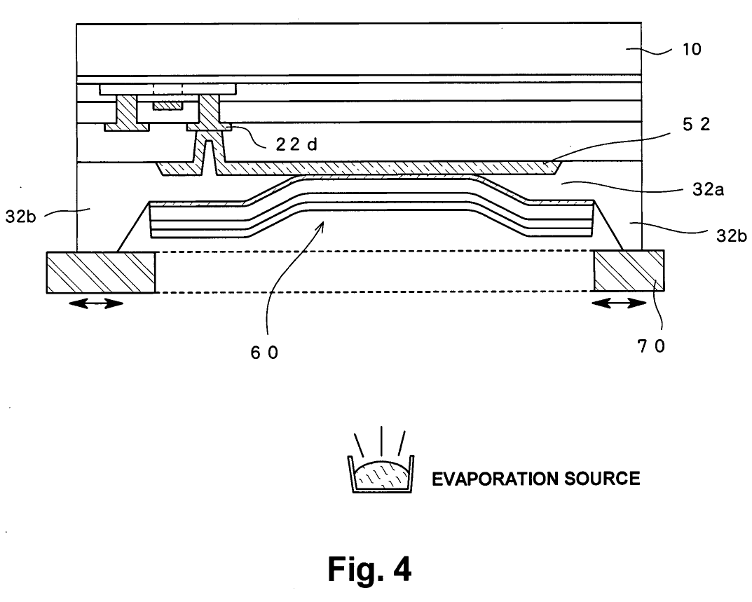

According to the present embodiment, after formation of the edge covering portion 32a and the mask supporting portion 32b having a greater thickness (height) in the second planarization insulating layer 32, a deposition source is heated and the organic layer 60 is formed by lamination covering the exposed surface of the pixel electrode 52 on the substrate using a deposition mask 70. The deposition mask 70 has an opening pattern which is larger than the opening portion of the second planarization insulating layer 32 through which the surface of the pixel electrode 52 is exposed as shown in FIG. 4, and which terminates on the inner region with respect to the mask supporting portion 32b. The organic layer 60 is formed by sequentially laminating a hole injection layer 62, a hole transport layer 64, an emissive layer 66, and an electron transport layer 68 in this order from the side of the anode 52.

In the present embodiment, although the same material may be used for the hole injection layer 62, the hole transport layer 64, and the electron transport layer 68, namely charge transport layers, and so on, which are used for emitting different colors, all of these layers, not just the emissive layer 66, are formed into a pattern corresponding to each pixel and terminating on the inner region with respect to the mask supporting portion 32 in each pixel, using the deposition mask 70 having an opening pattern for each pixel. In particular, in this embodiment, the hole injection layer 62 and the hole transport layer 64, which are formed prior to the formation of the emissive layer 66, are formed in such a manner that, as with the emissive layer 66, the end portions of these layers are located on the inner region with respect to the region where the mask supporting portion 32b is formed, so as to prevent these layers from being formed on the top surface of the mask supporting portion 32b. In this manner, damage to these layers and generation of dust can be prevented at the time of aligning the deposition mask 70. Further, in subsequent processes such as a cathode 54 forming process or other following processes, the thickness of the mask supporting portion 32b can help prevent the organic layers from being directly hit and damaged during the transportation of the substrate.

The end portions of the organic layer 60 must be located on the inner region with respect to the region where the mask supporting portion 32b is formed, and must also extend to the outer region with respect to the opening portion of the second planarization insulating layer 32 (corresponding to the light emission region), namely on the outer region with respect to the boundary portion between the edge covering portion 32a and the pixel electrode 52 (in other words, a portion where the edge covering portion 32a terminates on the pixel electrode). By forming the organic layer 60 on the outer region with respect to the opening portion of the second planarization insulating layer 32, namely covering the region where the edge covering portion 32a is formed, the organic layer 60 can reliably cover the region corresponding to the opening portion of the second planarization insulating layer 32, thereby reducing variations in the light emission area for each pixel, even when there is a slight deviation of the position of the organic layer 60. In addition, when the end portions of the organic layer 60 are located at the boundary between the opening portion of the second planarization insulating layer 32 and the edge covering portion 32a, a significant step is formed, and this may cause problems such as that the cathode 54, which is formed over the organic layer 60 as a common electrode for all the pixels, is disconnected at this step, or that the exposed anode 52 and cathode 54 short circuit. The structure of the present embodiment as described above can reliably prevent these and other problems.

Although the relationship of the sizes (areas) of the respective layers constituting the organic layer 60 is not particularly limited, when an upper layer is formed to be slightly smaller than a lower layer, it is possible to prevent the upper layer from covering corners of the end portions of the lower layer, to prevent cracks occurring at these corners, and to thereby prevent formation of deficient light emission regions at such cracks.

When the layers constituting the organic layer 60 are formed using a single deposition mask 70, after formation of the second planarization insulating layer 32 (32a, 32b), the deposition mask 70 is brought into contact with the top surface (in FIG. 4, positioned under the mask supporting portion 32b) of the mask supporting portion 32b, and is finely adjusted by moving the deposition mask as necessary such that the each opening portion of the mask overlaps the exposed surface (light emission region) of the corresponding pixel electrode 52. After alignment of the mask, the evaporation source containing a hole injection material is heated and the hole injection layer 62 is formed on the surface of the pixel electrode 52. Subsequently, the material to be deposited is sequentially changed to a hole transport material, an emissive material, and an electron transport material, or deposition chambers are changed, so that the hole transport layer 64, the emissive layer 66, and the electron transport layer 68 are sequentially laminated. Further, even when different deposition masks 70 having different opening sizes or the like are used for each or any of the layers constituting the organic layer 70, the respective layers can be formed in substantially the same manner as when a single mask is used, except that in this case it is necessary to finely adjust the position of the mask 70 while it is being held on the mask supporting portion 32b each and every time the mask is changed.

Then, the cathode 54, which is made of a metal such as Al or which has a laminated structure of LiF/Al sequentially accumulated from the side of the electron transport layer 68, is formed so as to cover substantially the entire surface of the substrate including the electron transport layer 68 (which is the uppermost layer of the organic layer 70), the edge covering portion 32a, and the mask supporting portion 32b. After removal of the deposition mask 70 used for forming the organic layer, the cathode 54 may be formed using vacuum evaporation in a manner similar to that used to form the organic layer.

The following are example materials and thicknesses of the respective layers constituting the organic EL element 50, described in order from the lowermost layer:

(i) anode 52: ITO or the like; thickness of approximately 60 nm to 200 nm

(ii) hole injection layer 62: copper phthalocyanine (CuPc), CFx, or the like; approximately 0.5 nm

(iii) hole transport layer 64: NPB (N,N′-di(naphthalene-1-yl)-N,N′-diphenyl-benzidine) or the like: 150 nm to 200 nm

(iv) organic emissive layer 66: a different material for each R, G, and B and a combination thereof; 15 nm to 35 nm each

(v) electron transport layer 68: Alq (aluminum quinolinol complex) or the like; approximately 35 nm

(vi) cathode 54: laminate structure comprising LiF (electron injection layer) and Al; approximately 0.5 nm to 1.0 nm (LiF layer), approximately 300 nm to 400 nm (Al layer)

It is preferable that the difference in height between the mask supporting portion 32b and the edge covering portion 32a of the second planarization insulating layer 32 is greater than the total thickness of the organic layer 60. With such a difference in height, the deposition mask can be reliably supported on the top surface of the mask supporting portion 32b during film alignment and deposition for forming any layer of the organic layer 60. As a result, it is possible to prevent the mask from coming into contact with the surface of the layers of the organic layer which have already been formed, which in turn reliably suppresses removal of the organic layer or mixture of dust caused by contacting the deposition mask with the organic layer.

When low molecule organic materials are used for the organic layer 60, the thickness thereof is usually smaller than 300 nm (approximately 200 nm to 271 nm in the above example). In such a case, it is sufficient that the difference in height between the edge covering portion 32a and the top surface of the mask supporting portion 32b (the mask supporting surface) is approximately 300 nm.

When an organic resin is used for the second planarization material, the thickness (height) of the edge covering portion 32a may be approximately 200 nm, for example, and the thickness (height) of the mask supporting portion 32b is approximately 1 μm, for example. When an insulating material such as TEOS is used for the second planarization insulating layer 32, by forming the edge covering portion 32a to have a height of approximately 200 nm and forming the mask supporting portion 32b to have a height of approximately 500 to 700 nm, the difference in height between the mask supporting portion 32b and the edge covering portion 32a can be greater than the total thickness of the organic layer 60, so that the mask can be reliably supported while the organic layer is protected.

Further, because the height of the edge covering portion 32a is set to approximately 200 nm, which is relatively low for a planarization insulating layer, the boundary between the edge covering portion 32a and the opening portion of the planarization insulating layer 32 forms only a moderate slope. It is therefore possible to reliably prevent cracks or the like developing in the organic layer at this boundary.

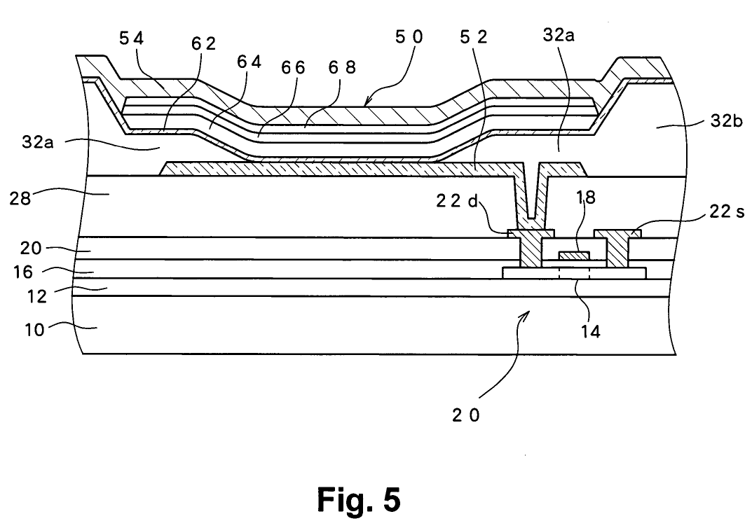

FIG. 5 schematically shows a cross section of the principal portion of the pixel portion of the organic EL panel according to a second embodiment. The configuration of the second embodiment differs from the above-described Embodiment 1 in that, when the lower individual electrode is an anode, just the hole injection layer 62, which is the lowermost layer of the organic layer 60, is formed over the entire surface of the substrate, including the mask supporting surface of the mask supporting portion 32b. Each of other layers constituting the organic layer 60 is, of course, formed in an individual pattern for each pixel similar to the first embodiment, and each layer terminates on the inner region with respect to the mask supporting portion 32b.

The hole injection layer 62 is formed from a material having relatively high mechanical strength and high adhesion to lower layers, such as CuPc or CFx (where x is a natural number), regardless of the emission color. Further, the hole injection layer 62 is formed to have a thickness of approximately 0.5 nm, which is very thin compared to other layers of the organic layer 60. For these reasons, the hole injection layer 62 can resist contact with the deposition mask 70 when the mask is finely adjusted by moving the mask while the mask is in contact with the mask supporting portion 32b.

Accordingly, in the embodiment 2, the hole injection layer 62 is formed over the entire surface of the substrate without using the deposition mask used for individual pattern for each pixel, and each of the hole transport layer 64, the emission layer 66, and the electron transport layer 68, which has low mechanical strength and is thicker than 1 nm, is formed in an individual pattern for each pixel so as not to cover the mask supporting surface of the mask supporting portion 32b.

By forming the hole injection layer 62 as a common layer for all pixels, and not as an individual pattern for each pixel, the time and labor required for alignment of the dedicated mask can be conserved. Further, because the hole injection layer 62, when formed as a common layer, is additionally provided between the lower anode 52 and the upper cathode 54, the covering ability of the cathode 54 and the voltage resistance of both electrodes are increased accordingly.

While the preferred embodiments of the present invention have been described using specific terms, such description is for illustrative purposes only, and it is to be understood that changes and variations may be made without departing from the spirit or scope of the appended claims.

What is claimed is:

1. An organic electroluminescence panel in which a plurality of organic electroluminescence elements are formed above a substrate, each organic electroluminescence element including at least an organic layer including an organic emissive material between a lower individual electrode which is individually patterned for each pixel and an upper electrode, the organic electroluminescence panel comprising:
an edge covering insulating layer for covering peripheral end portions of the lower individual electrode, and
a mask supporting insulating layer, which is formed on an outer peripheral region with respect to the edge covering insulating layer and has a greater thickness than the edge covering insulating layer, for supporting a mask, which is used when forming the organic layer, on a top surface thereof,
wherein the organic layer terminates on an outer region with respect to the boundary between the edge covering insulating layer and the lower individual electrode, and on an inner region with respect to a region where the mask supporting insulating layer is formed, and the organic layer is individually patterned for each pixel.

2. An organic electroluminescence panel according to claim 1, wherein
the organic layer includes at least a hole injection layer and an organic emissive layer each formed by vacuum evaporation, and
each of the hole injection layer and the organic emissive layer terminates on the inner region with respect to a region where the mask supporting insulating layer is formed.

3. An organic electroluminescence panel according to claim 2, wherein
a charge transport layer is formed between the hole injection layer and the organic emissive layer and/or between the organic emissive layer and the upper electrode, and
the charge transport layer terminates on the outer region with respect to the boundary between the edge covering insulating layer and the lower individual electrode, and on the inner region with respect to a region where the mask supporting insulating layer is formed, and the charge transport layer is individually patterned for each pixel.

4. An organic electroluminescence panel according to claim 1, wherein
the edge covering insulating layer and the mask supporting insulating layer are formed by patterning a single insulating layer in respective predetermined patterns having different thicknesses by means of multi-phase exposure or gray-tone exposure.

5. An organic electroluminescence panel in which a plurality of organic electroluminescence elements are formed above a substrate, each organic electroluminescence element including at least an organic layer including an organic emissive material between a lower individual electrode which is individually patterned for each pixel, and an upper electrode, the organic electroluminescence panel comprising:
an edge covering insulating layer for covering peripheral end portions of the lower individual electrode, and
an upper insulating layer which is formed on an outer peripheral region with respect to the edge covering insulating layer and has a greater thickness than the edge covering insulating layer,
wherein the organic layer terminates on an outer region with respect to the boundary between the edge covering insulating layer and the lower individual electrode, and on an inner region with respect to a region where the upper insulating layer is formed, and the organic layer is individually patterned for each pixel.

6. An organic electroluminescence panel according to claim 5, wherein
the organic layer includes at least a hole injection layer and an organic emissive layer each formed by vacuum evaporation, and
each of the hole injection layer and the organic emissive layer terminates on the inner region with respect to a region where the upper insulating layer is formed.

7. An organic electroluminescence panel according to claim 6, wherein
a charge transport layer is formed between the hole injection layer and the organic emissive layer and/or between the organic emissive layer and the upper electrode, and
the charge transport layer terminates on the outer region with respect to the boundary between the edge covering insulating layer and the lower individual electrode, and on the inner region with respect to a region where the upper insulating layer is formed, and the charge transport layer is individually patterned for each pixel.

8. An organic electroluminescence panel according to claim 5, wherein
the edge covering insulating layer and the upper insulating layer are formed by patterning a single insulating layer in respective predetermined patterns having different thicknesses by means of multi-phase exposure or gray-tone exposure.

9. An organic electroluminescence panel in which a plurality of organic electroluminescence elements are formed above a substrate, each organic electroluminescence element including at least a hole injection layer and an organic emissive layer between a lower individual electrode which is individually patterned for each pixel and an upper electrode, the organic electroluminescence panel, comprising:
an edge covering insulating layer for covering peripheral end portions of the lower individual electrode, and
a mask supporting insulating layer, which has a greater thickness than the edge covering insulating layer, for supporting a mask, which is used when forming an organic layer, on a top surface thereof, wherein
the hole injection layer is formed covering the lower individual electrode, the edge covering insulating layer, and the mask supporting insulating layer, and
the organic emissive layer is formed between the upper electrode and the hole injection layer and terminates on an outer region with respect to the boundary between the edge covering insulating layer and the lower individual electrode, and on an inner region with respect to a region where the mask supporting insulating layer is formed, and the organic emissive layer is individually patterned for each pixel.

10. An organic electroluminescence panel according to claim 9, wherein
the hole injection layer has a thickness which is smaller than 10 nm, and the organic emissive layer has a total thickness of 10 nm or greater.

11. An organic electroluminescence panel according to claim 10, wherein
a charge transport layer is formed between the hole injection layer and the organic emissive layer and/or between the organic emissive layer and the upper electrode, and
the charge transport layer terminates on the outer region with respect to the boundary between the edge covering insulating layer and the lower individual electrode, and on the inner region with respect to a region where the mask supporting insulating layer is formed, and the charge transport layer is individually patterned for each pixel.

12. An organic electroluminescence panel according to claim 9, wherein
the edge covering insulating layer and the mask supporting insulating layer are formed by patterning a single insulating layer in respective predetermined patterns having different thicknesses by means of multi-phase exposure or gray-tone exposure.
